(19) United States
(12) Patent Application Publication
(10) Pub. No.: US 2025/0324858 A1
(43) Pub. Date: Oct. 16, 2025

(54) INSERTION OF ETCH STOPPER LAYER FOR OLED ADVANCED PATTERNING

(71) Applicant: Applied Materials, Inc., Santa Clara, CA (US)

(72) Inventors: Sheng-Wen WANG, Tainan City (TW); Chung-chia CHEN, Hsinchu City (TW); Ji Young CHOUNG, Hwaseong-si (KR); Yu-Hsin LIN, Zhubei City (TW)

(21) Appl. No.: 19/092,705

(22) Filed: Mar. 27, 2025

Related U.S. Application Data
(60) Provisional application No. 63/633,187, filed on Apr. 12, 2024.

(51) Int. Cl. H10K 59/122; H10K 59/12; H10K 59/80; H10K 71/20; H10K 102/10

(52) U.S. Cl. CPC H10K 59/122; H10K 59/1201; H10K 59/80518; H10K 59/873; H10K 71/233; H10K 2102/101

(57) ABSTRACT

Embodiments described herein relate to sub-pixel circuits and methods of forming sub-pixel circuits that may be utilized in a display such as an OLED display. The sub-pixel includes adjacent pixel structures disposed over a substrate and exposing a metal-containing layer of an anode, adjacent overhang structures disposed over an upper surface of the pixel structures, the overhang structures define the sub-pixel and include a first structure disposed over the upper surface of pixel structures, the first structure having a first composition, and a second structure disposed over the first structure, the second structure including an extension extending laterally past a sidewall of first structure, and a protective layer disposed between the pixel structures and the first structure of the overhang structures, and the protective layer includes a metal-containing material having a greater etch resistivity than the first composition of the first structure.

### CROSS-REFERENCE TO RELATED APPLICATIONS

This application claims priority to U.S. Provisional Patent Application Ser. No. 63/633,187 filed on Apr. 12, 2024, which is herein incorporated by reference in its entirety

### BACKGROUND

### Field

Embodiments described herein generally relate to a display. More specifically, embodiments described herein relate to sub-pixel circuits and methods of forming sub-pixel circuits that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. Top emission devices are classified based on whether or not the light emitted from the OLED device exits through the lid that is added following the fabrication of the device. OLEDs are used to create display devices in many electronics today. Today's electronics manufacturers are pushing these display devices to shrink in size while providing higher resolution than just a few years ago.

Therefore, a need exists for sub-pixel circuits and methods of forming sub-pixel circuits.

### SUMMARY

In one embodiment, a sub-pixel is provided. The sub-pixel includes adjacent pixel structures disposed over a substrate and exposing a metal-containing layer of an anode, adjacent overhang structures disposed over an upper surface of the pixel structures, the overhang structures define the sub-pixel and include a first structure disposed over the upper surface of pixel structures, the first structure having a first composition, and a second structure disposed over the first structure, the second structure including an extension extending laterally past a sidewall of first structure, and a protective layer disposed between the pixel structures and the first structure of the overhang structures, the protective layer includes a metal-containing material having a greater etch resistivity than the first composition of the first structure, an organic light-emitting diode (OLE) material disposed over the anode, and a cathode disposed over the OLE material.

In another embodiment, a sub-pixel circuit is provided. The sub-pixel includes pixel structures disposed over a substrate, the pixel structures exposing a metal-containing layer of an anode, overhang structures disposed over an upper surface of the pixel structures, the overhang structures define a plurality of sub-pixels and include a first structure disposed over the upper surface of pixel structures, the first structure comprising a first composition, and a second structure disposed over the first structure, the second structure including an extension extending laterally past a sidewall of first structure, and a protective layer disposed between the pixel structures and the first structure of the overhang structures, the protective layer includes a metal-containing material having a greater etch resistivity than the first composition of the first structure, an organic light-emitting diode (OLE) material disposed over the anode, and a cathode disposed over the OLE material.

In another embodiment, a method of forming a sub-pixel is provided. The method includes depositing a protective material, a first structure layer, and a second structure layer over a substrate, adjacent pixel structures are disposed over the substrate and expose a metal-containing layer of an anode, disposing and patterning a resist over the second structure layer to expose a pixel opening, conducting an etching process to remove the second structure layer of the pixel opening to form a second structure of adjacent overhang structures, conducting a first etching process to remove the first structure layer of the pixel opening to form a first structure of the adjacent overhang structures, the protective material is resistant to a first etch chemistry of the first etching process, and conducting a second etching process to remove the protective material of the pixel opening to form a protective layer disposed between the pixel structures and the first structure of the adjacent overhang structures, the metal-containing layer of the anode is resistant to a second etch chemistry of the second etching process.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIGS. 1A and 1B are schematic, cross-sectional views of a sub-pixel circuit, according to embodiments.

FIGS. 2A and 2B schematic, cross-sectional views of overhang structures, according to embodiments.

FIGS. 3A-3F are schematic, cross-sectional views of a sub-pixel during a method for forming the sub-pixel circuit, according to embodiments.

FIG. 4 is a schematic block diagram of a method of forming a sub-pixel circuit, according to one or more embodiments.

FIG. 5A-5B are schematic, cross-sectional views of a sub-pixel during the method, according to embodiments described herein.

FIG. 6 is a schematic block diagram of a method of forming a sub-pixel circuit, according to one or more embodiments.

FIGS. 7A-7B are schematic, cross-sectional views of a sub-pixel during the method, according to embodiments described herein.

FIG. 8 is a schematic block diagram of a method of forming a sub-pixel circuit, according to one or more embodiments.

FIGS. 9A-9B are schematic, cross-sectional views of a sub-pixel 104 during the method, according to embodiments described herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to a display. More specifically, embodiments described herein relate to sub-pixel circuits and methods of forming sub-pixel circuits that may be utilized in a display such as an organic light-emitting diode (OLED) display.

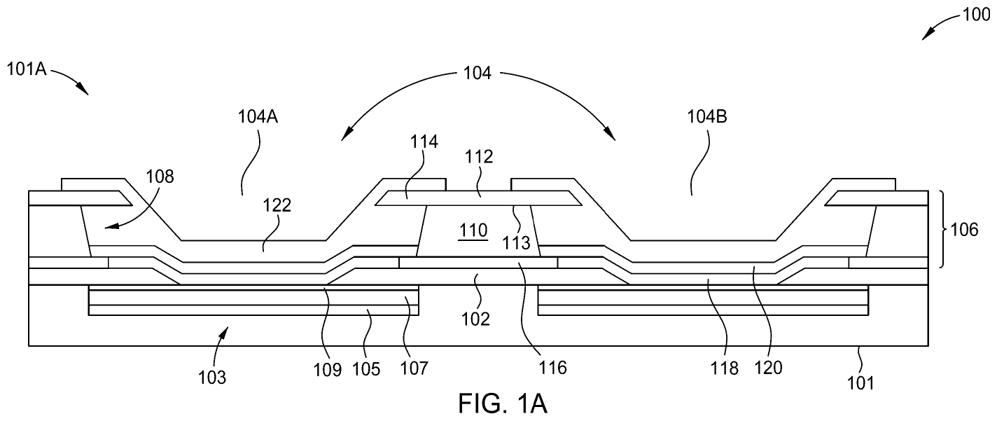

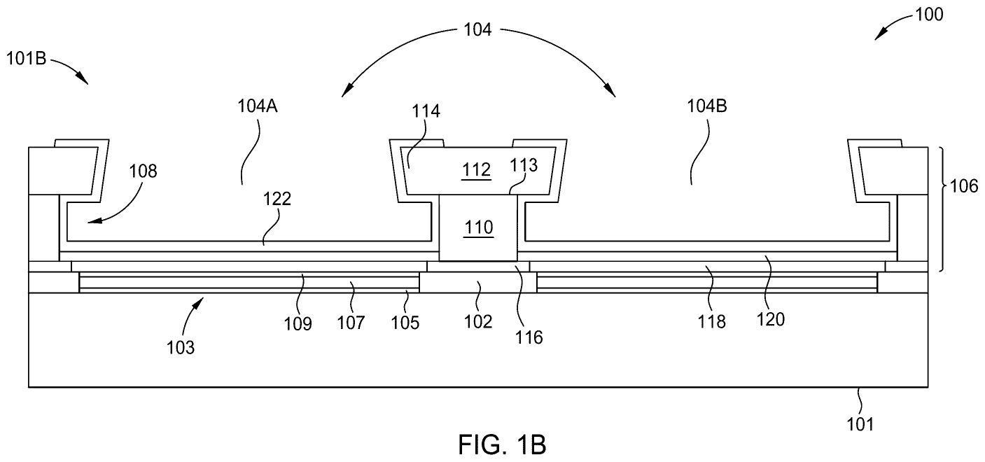

FIGS. 1A and 1B are schematic, cross-sectional views of a sub-pixel circuit 100. The sub-pixel circuit 100 of FIG. 1A has a pixel structure arrangement 101A. The sub-pixel circuit 100 of FIG. 1B has a second pixel structure arrangement 101B. The pixel structure arrangement 101A includes pixel structures (PS) 102 above an anode 103. The second pixel structure arrangement 101B includes PS 102 on the same plane as the anode. The sub-pixel circuit 100 includes a substrate 101. The anode 103 includes at least one metal-containing layer disposed over, and in some embodiments on, the substrate 101. The anode includes an anode layer stack disposed over, and in some embodiments on, the substrate 101. The anode 103 is defined by adjacent PS 102 disposed over, and in some embodiments on, the substrate 101. The anode layer includes a first metal-containing layer 105, a second metal-containing layer 107 disposed on the first metal-containing layer 105, and a third metal-containing layer 109 disposed on the second metal-containing layer 107. The first metal-containing layer 105 and the third metal-containing layer 109 include the same metal-containing material, in some embodiments. For example, the first metal-containing layer 105 and the third metal-containing layer 109 include indium tin oxide (ITO), and the second metal-containing layer 107 includes silver. The metal-containing materials of the first, second, and third metal-containing layers 105, 107, 109 include, but are not limited to, chromium, titanium, gold, silver, copper, aluminum, ITO, indium zinc oxide (IZO), indium gallium zinc oxide (IGZO), or combinations thereof.

The plurality of PS 102 are disposed over, and in some embodiments on, the substrate 101. The PS 102 include one of an organic material, an organic material with an inorganic coating disposed thereover, or an inorganic material. The organic material of the PS 102 includes, but is not limited to, polyimides. The inorganic material of the PS 102 includes, but is not limited to, silicon oxide (SiO₂), silicon nitride (Si₃N₄), silicon oxynitride (Si₂N₂O), magnesium fluoride (MgF₂), or combinations thereof. Adjacent PS expose and define the anode 103. I.e., the third metal-containing layer 109 of the anode layer stack is exposed by the PS 102. The sub-pixel circuit 100 has a plurality of sub-pixels 104 including at least a first sub-pixel 104A and a second sub-pixel 104B. While the Figures depict the first sub-pixel 104A and the second sub-pixel 104B, the sub-pixel circuit 100 of the embodiments described herein may include two or more sub-pixels 104, such as a third and a fourth sub-pixel. Each sub-pixel 104 has organic light emitting (OLE) materials configured to emit a white, red, green, blue, white, yellow or other color light when energized. E.g., the OLE materials of the first sub-pixel 104A emits a red light when energized, the OLE materials of the second sub-pixel 104B emits a green light when energized, the OLE materials of a third sub-pixel emits a blue light when energized, and the OLE materials of a fourth sub-pixel emits another color light when energized.

The sub-pixel circuit 100 includes a plurality of overhang structures 106. Each sub-pixel 104 is defined by adjacent overhang structures 106. The overhang structures 106 are permanent to the sub-pixel circuit 100. The overhang structures 106 have overhangs 108. Each overhang 108 are defined by an extension 114 of a second structure 112 extending laterally past an upper surface 113 of a first structure 110. The first structures 110 are disposed over the PS 102. The first structure 110 includes a conductive material or a non-conductive inorganic material. The second structure 112 includes a conductive material or a non-conductive inorganic material. The conductive material includes aluminum (Al), aluminum neodymium (AlNd), molybdenum (Mo), molybdenum tungsten (MoW), copper (Cu), titanium (Ti), chromium (Cr), a transparent conductive oxide (TCO) material, or combination thereof. The TCO material includes, but is not limited to, indium zinc oxide (IZO), indium tin oxide (ITO), indium gallium zinc oxide (IGZO), or combinations thereof. The non-conductive inorganic material includes silicon nitride (Si₃N₄), silicon oxide (SiO₂), silicon oxynitride (Si₂N₂O), or combinations thereof. The first structure 110 and the second structure include a different composition of material. The overhang structures 106 are able to remain in place, i.e., are permanent.

A protective layer 116 is disposed between the first structures 110 and the PS 102. The protective layer 116 prevents damage to the metal-containing layer of the anode 103, during etching of a first structure layer 304 to form the first structures 110. During etching of the first structure layer 304 a first etch chemistry is used. The first etch chemistry may be a wet etch chemistry or a dry etch chemistry. In some embodiments, the wet etch chemistry of the first etch chemistry is acidic. In other embodiments, the first etch chemistry includes, but is not limited to, tetramethylammonium hydroxide (TMAH) or an ammonia-peroxide mixture (APM). The protective layer 116 has lower etch rate than the first structures 110 when exposed to the first etch chemistry. E.g., the protective layer 116 is an etch stop layer. For example, the protective layer 116 is resistant to an acidic wet etch chemistry.

The protective layer 116 is etchable via a second etch chemistry. The second etch chemistry is different from the first etch chemistry. The second etch chemistry may be a wet etch chemistry or a dry etch chemistry. The wet etch chemistry of the second etch chemistry includes, but is not limited to, acid, hydrogen peroxide (H₂O₂), TMAH, or APM. The second etch chemistry will not etch the metal-containing layer of the anode 103.

The overhang extensions 114 of the second structures forms the overhangs 108 and enables the second structures 112 to shadow the first structures 110. The shadowing of the overhangs 108 provides for evaporation deposition of an OLE material 118 and a cathode 120. The OLE material 118 may include one or more of a HIL, a HTL, an EML, and an ETL. The OLE material 118 is disposed over, and in some embodiments in contact with, the metal-containing layer of the anode 103. The OLE material 118 is disposed under the overhangs 108, i.e., the shadow of the second structures 112. The cathode 120 includes a conductive material, such as a metal. E.g., the cathode 120 includes, but is not limited to, silver, magnesium, chromium, titanium, aluminum, ITO, or combinations thereof. The cathode 120 may include a different material than both of the second structures 112 and the first structures 110. The cathode 120 may include a different material than one of the second structures 112 and the first structures 110. The cathode 120 is disposed over, and in some embodiments in contact with, the OLE material 118. The cathode 120, in some embodiments, contacts a sidewall of the first structures 110. In other embodiments, the cathode 120 has an endpoint before the first structures 110. I.e., the cathode 120 does not contact the sidewall of the first structures 110.

Each sub-pixel 104 includes an encapsulation layer 122. The encapsulation layer 122 may be or may correspond to a local passivation layer. The encapsulation layer 122 of a respective sub-pixel is disposed over the cathode 120 (and OLE material 118) with the encapsulation layer 122 extending under at least a portion of each of the overhangs 108. The encapsulation layer 122 includes the non-conductive inorganic material, such as the silicon-containing material. The encapsulation layer 122 is disposed over the cathode, where the encapsulation layer 122 extends under at least a portion of the overhang structures 106 past the cathode 120 along the sidewall of the first structures 110, and contacts the bottom surface of the second structures 112 of the overhang structures 106.

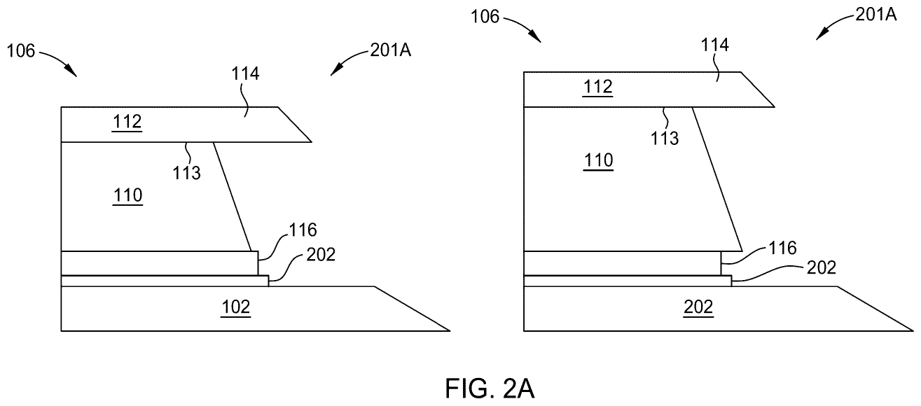

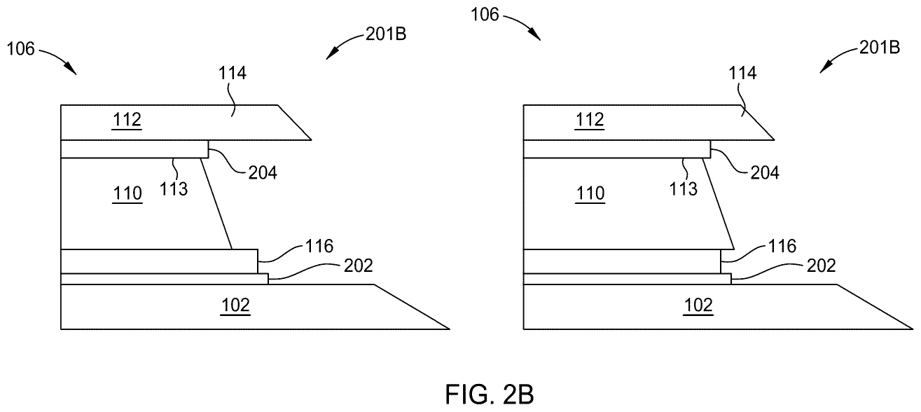

FIGS. 2A and 2B are schematic, cross-sectional views of overhang structures 106. The overhang structures 106 of FIG. 2A has a first overhang arrangement 201A. The overhang structures 106 of FIG. 2B has a second overhang arrangement 201B. The overhang structures 106 of the sub-pixel circuit 100 may include one of the first overhang arrangement 201A or the second overhang arrangement 201B. The first overhang arrangement 201A include a first adhesion layer 202 in contact with the PS 102, the protective layer 116 in contact with the first adhesion layer 202, the first structure 110 in contact with the protective layer 116, and the second structure 112 in contact with the first structure 110. The first adhesion layer 202 adheres the protective layer 116 to the PS 102. In the second overhang arrangement 201B, the first adhesion layer 202 is in contact with the PS 102, the protective layer 116 is in contact with the first adhesion layer 202, the first structure 110 is in contact with the protective layer 116, and a second adhesion layer 204 is in contact with the second structure 112. In some embodiments, the first structure 110 and the second structure 112 include the conductive material. The first structure 110 and the second structure include a different composition of material. The protective layer 116 includes a metal-containing material having an etch resistivity to the first etch chemistry greater than the etch resistivity of the conductive material of the first structures 110 to the first etch chemistry.

The protective layer 116 includes, but is not limited to, copper, copper alloy, Ti, Ti alloy, TiN, Mo, MoN, Mo alloy, TCO, or combinations thereof. The protective layer 116 includes a material of a different composition than the first adhesion layer 202 and the second adhesion layer 204. In one example, the first overhang arrangement 201A includes the first adhesion layer 202 of Mo, the protective layer 116 of Cu or Cu alloy, the first structure 110 of Mo, and the second structure of Ti. In another example, the second overhang arrangement 201B includes the first adhesion layer 202 of Mo, the protective layer 116 of Cu or Cu alloy, the first structure 110 of Al, the second adhesion layer 204 of Mo, and the second structure of Ti. The first adhesion layer 202 is an optional layer. In some embodiments, (right of FIGS. 2A and 2B) the protective layer 116 and the first adhesion layer 202 include a width less than a width of the bottom surface of the first structure 110. In other embodiments, (left of FIGS. 2A and 2B) the protective layer 116 and the first adhesion layer 202 include a width greater than a width of the bottom surface of the first structure 110.

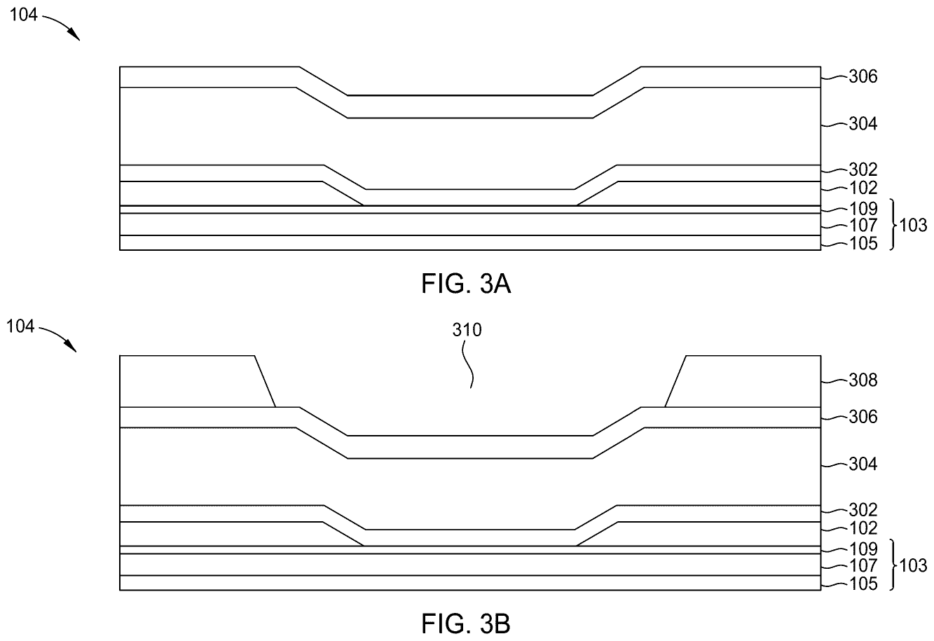

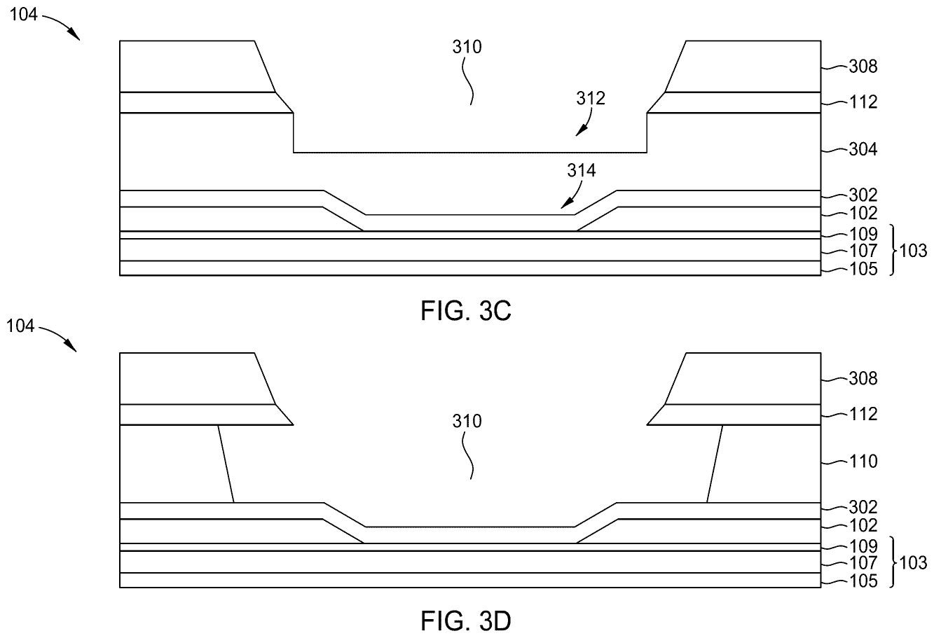

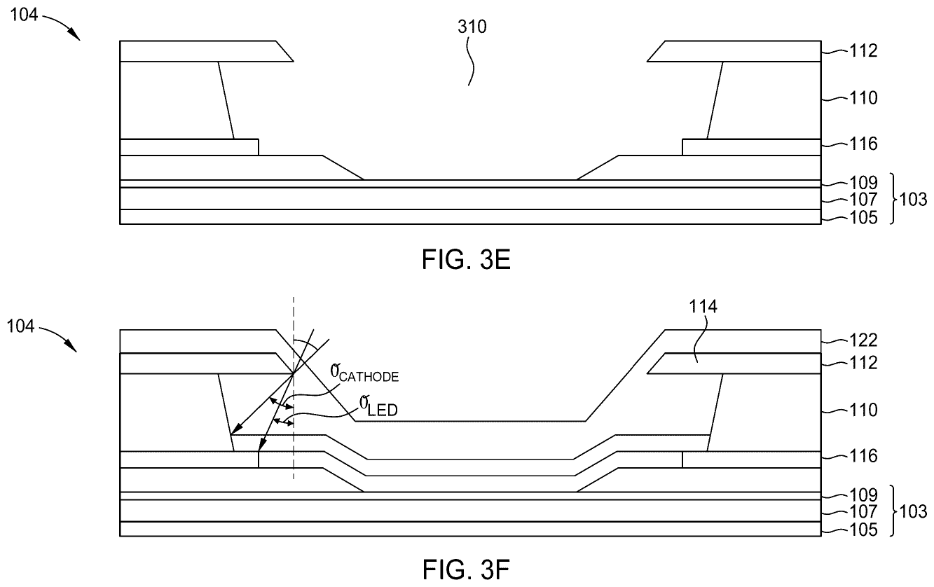

FIGS. 3A-3F are schematic, cross-sectional views of a sub-pixel 104 during a method for forming the sub-pixel circuit 100. At a first operation, as shown in FIG. 3A, a protective material 302, a first structure layer 304, and a second structure layer 306 are deposited over the substrate 101. The protective material 302 is disposed over the PS 102 and the anode 103. The second structure layer 306 is disposed over the first structure layer 304. The first structure layer 304 corresponds to the first structure 110 and the second structure layer 306 corresponds to the second structure 112 of the overhang structures 106. In embodiments including the first adhesion layer 202, the first adhesion layer 202 is disposed between the protective material 302 and the PS 102. In embodiments including the second adhesion layer 204, the second adhesion layer 204 is disposed between the first structure layer 304 and the second structure layer 306.

At a second operation, as shown in FIG. 3B, a resist 308 is disposed and patterned. The resist 308 is disposed over the second structure layer 306. The patterning is one of a photolithography, digital lithography process, or laser ablation process. The resist 308 is then exposed to a developer such that the resist 308 is patterned. The resist 308 is patterned to form a pixel opening 310 of a sub-pixel 104. At a third operation, as shown in FIG. 3C, an etching process is performed. The etching process removes the second structure layer 306 in the pixel opening 310 to form the second structure 112. The second adhesion layer 204 exposed by the pixel opening 310 is also removed. An upper portion 312 of the first structure layer 304 exposed by the pixel opening 310 is removed by the etching process. At a fourth operation, as shown in FIG. 3D, a first etch process is performed. The first etch process may be a wet or dry etch process. The first etch process removes a lower portion 314, i.e., the remaining first structure layer 304 exposed by the pixel opening 310. A first etch chemistry is used. The first etch chemistry may be a wet etch chemistry or a dry etch chemistry. In some embodiments, the wet etch chemistry of the first etch chemistry is acidic. In other embodiments, the first etch chemistry includes, but is not limited to, tetramethylammonium hydroxide (TMAH) or an ammonia-peroxide mixture (APM). The protective layer 116 is lower etch rate than the first structures 110 when exposed to the first etch chemistry. E.g., the protective layer 116 is an etch stop layer.

At a fifth operation, as shown in FIG. 3E, a second etch process is performed. A second etch chemistry is used. The second etch chemistry is different from the first etch chemistry. The first etch chemistry may be a wet etch chemistry or a dry etch chemistry. The wet etch chemistry of the second etch chemistry includes, but is not limited to, acid, hydrogen peroxide (H₂O₂), TMAH, or APM. The first adhesion layer 202 exposed by the pixel opening 310 is also removed by the second etch process.

At a sixth operation, as shown in FIG. 3F, the OLE material 118, the cathode 120, and the encapsulation layer 122 are deposited. The shadowing of the overhang 108 provides for evaporation deposition each of the OLE material 118 and a cathode 120. The shadowing effect of the overhang structures 106 define the OLED angle θ_{OLED} of the OLE material 118 and the cathode angle θ_{cathode} of the cathode 120. The OLED angle θ_{OLED} of the OLE material 118 and the cathode angle θ_{cathode} of the cathode 120 result from evaporation angle set by the evaporation source and the extension 114 of the second structures 112 extending laterally past the upper surface 113 of the first structures 110. The encapsulation layer 122 is disposed over the cathode 120 (and OLE material 118) with the encapsulation layer 122 extending under at least a portion of each of the overhangs 108. The encapsulation layer 122 includes the non-conductive inorganic material, such as the silicon-containing material. The encapsulation layer 122 is disposed over the cathode, where the encapsulation layer 122 extends under at least a portion of the overhang structures 106 past the cathode 120 along the sidewall of the first structures 110, and contacts the bottom surface of the second structures 112 of the overhang structures 106.

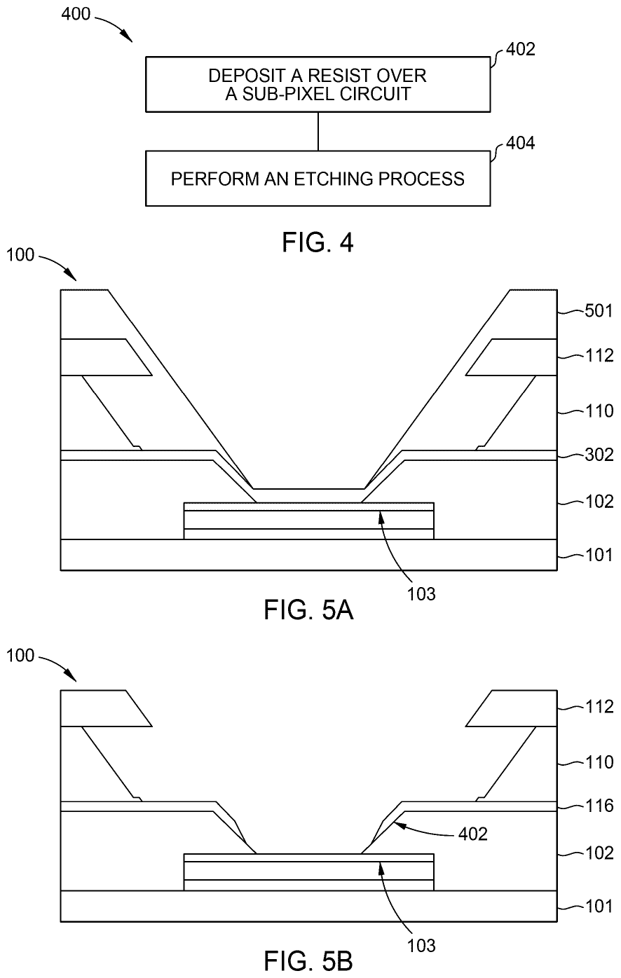

FIG. 4 is a schematic block diagram of a method 400 of forming a sub-pixel circuit 100, according to one or more embodiments. FIG. 5A-5B are schematic, cross-sectional views of a sub-pixel 104 during the method, according to embodiments described herein. At operation 402 as shown in FIG. 5A, a resist 501 is disposed over adjacent PS 102, adjacent first structures 110, adjacent second structures 112, and at least a portion of the protective material 302. A photolithography process is performed to form a pattern within the resist 501. One or more gaps are patterned within the resist using the photolithography process. In one or more embodiments, after the photolithography process, a gap extends through the resist 501. A portion of the protective material 302 disposed over the anode 103 is exposed by the gap. In one or more embodiments, the portion of the protective material 302 disposed over the anode 103 disposed between the adjacent PS 102.

At operation 404 as shown in FIG. 5B, an etching process is performed to remove the portion of the protective material 302 disposed over the anode 103 is exposed by the gap. In one or more embodiments, the etching process is a dry etching process. The resist 501 is removed after the etching process. The etching problem forms the protective layer 116 formed over the adjacent PS 102 and extending under the adjacent first structures 110. A portion of an upper surface of the anode 103 is exposed after the etching process. The resist 501 is stripped after the etching process is performed.

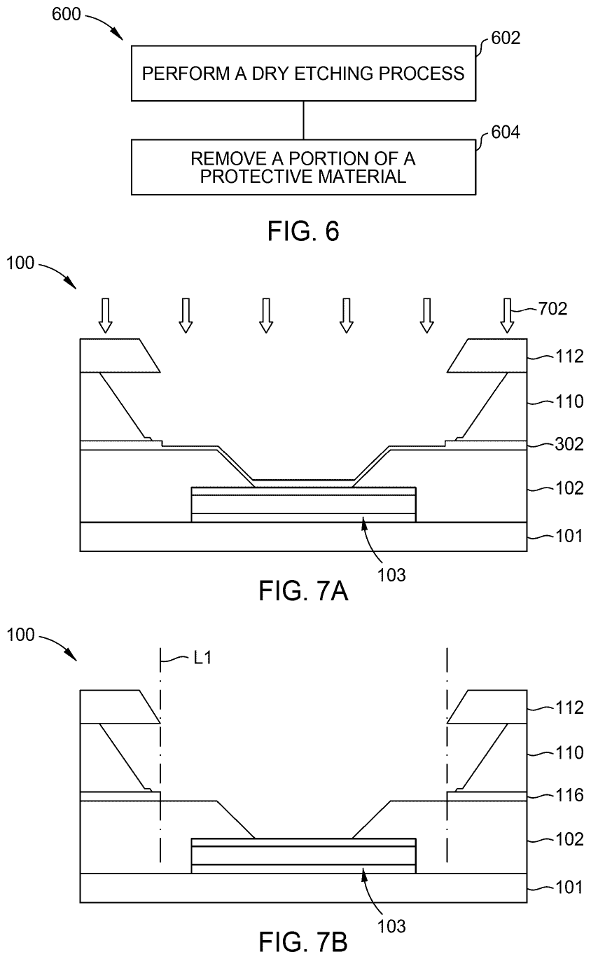

FIG. 6 is a schematic block diagram of a method 600 of forming a sub-pixel circuit 100, according to one or more embodiments. FIGS. 7A-7B are schematic, cross-sectional views of a sub-pixel 104 during the method, according to embodiments described herein. At operation 602 as shown in FIG. 7A a dry etching process is performed. As depicted in FIG. 7A a dry etchant is applied to the sub-pixel circuit 100. The adjacent overhangs formed by the adjacent second structures 112 extending past a sidewall of the adjacent first structures 110. The portion of the second structure 112 extending past the first structure 110 defines a shadow region. The protective material 302 is disposed over adjacent PS 102 and extends over an upper surface of the anode 103.

At operation 604 as shown in FIGS. 7B, a portion of the protective material 302 is removed. The dry etchant 702 removes the portion of the protective material 302. The shadow region protects a portion of the protective material 302 disposed under the second structures 112. The portion of the protective material disposed under the second structures 112 and the first structures 110 defines the protective layer 116. An endpoint of the protective layer is vertically aligned with an endpoint of the second structure as shown with the reference line L1.

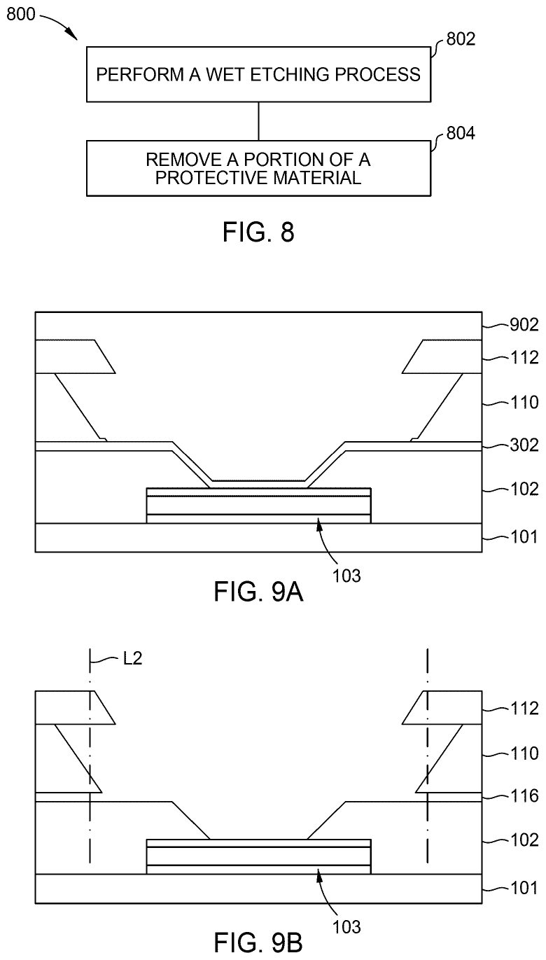

FIG. 8 is a schematic block diagram of a method 800 of forming a sub-pixel circuit 100, according to one or more embodiments. FIGS. 9A-9B are schematic, cross-sectional views of a sub-pixel 104 during the method, according to embodiments described herein. At operation 802 as shown in FIG. 9A a wet etching process is performed. As depicted in FIG. 9A a wet etchant 902 is applied to the sub-pixel circuit 100. The adjacent overhangs formed by the adjacent second structures 112 extending past a sidewall of the adjacent first structures 110. The protective material 302 is disposed over adjacent PS 102 and extends over an upper surface of the anode 103.

At operation 804 as shown in FIGS. 9B, a portion of the protective material 302 is removed. The wet etchant 902 removes the portion of the protective material 302. The first structure 110 protects a portion of the protective material 302 disposed under the first structure 110. The portion of the protective material 302 remaining after the wet etching process defines the protective layer 116. An endpoint of the first structure 110 extends vertically past an endpoint of the protective layer 116 as shown with the reference line L2.

While the foregoing is directed to embodiments of the present disclosure, other and further embodiments of the disclosure may be devised without departing from the basic scope thereof, and the scope thereof is determined by the claims that follow.

What is claimed is:

1. A sub-pixel, comprising:
adjacent pixel structures disposed over a substrate and exposing a metal-containing layer of an anode;
adjacent overhang structures disposed over an upper surface of the pixel structures, wherein the overhang structures define the sub-pixel and comprise:
a first structure disposed over the upper surface of pixel structures, the first structure comprising a first composition; and
a second structure disposed over the first structure, the second structure including an extension extending laterally past a sidewall of first structure;
a protective layer disposed between the pixel structures and the first structure of the overhang structures, the protective layer includes a metal-containing material having a greater etch resistivity than the first composition of the first structure;
an organic light-emitting (OLE) material disposed over the anode; and
a cathode disposed over the OLE material.

2. The sub-pixel of claim 1, wherein the anode includes an anode layer stack comprising a first metal-containing layer, a second metal-containing layer disposed on the first metal-containing layer, and a third metal-containing layer disposed on the second metal-containing layer.

3. The sub-pixel of claim 1, wherein a metal-containing layer of the anode comprises chromium, titanium, gold, silver, copper, aluminum, indium tin oxide (ITO), indium zinc oxide (IZO), indium gallium zinc oxide (IGZO), or combinations thereof.

4. The sub-pixel of claim 1, wherein a first adhesion layer is in contact with the pixel structures, the protective layer is in contact with the first adhesion layer, and the first structure is in contact with the protective layer.

5. The sub-pixel of claim 2, wherein a second adhesion layer is disposed between the first structure and the second structure.

6. The sub-pixel of claim 1, wherein the first composition comprises aluminum (Al), aluminum neodymium (AlNd), molybdenum (Mo), molybdenum tungsten (MoW), copper (Cu), titanium (Ti), chromium (Cr), a transparent conductive oxide (TCO) material, or combinations thereof.

7. The sub-pixel of claim 6, wherein the TCO material comprises IZO, ITO, IGZO, or combinations thereof.

8. The sub-pixel of claim 1, wherein the protective layer comprises copper, copper alloy, Ti, Ti alloy, TiN, Mo, MoN, Mo alloy, TCO, or combinations thereof.

9. The sub-pixel of claim 1, wherein the first structure and the second structure include a different composition of material.

10. The sub-pixel of claim 1, further comprising an encapsulation layer disposed over the cathode.

11. A sub-pixel circuit, comprising:
pixel structures disposed over a substrate, the pixel structures exposing a metal-containing layer of an anode;
overhang structures disposed over an upper surface of the pixel structures, wherein the overhang structures define a plurality of sub-pixels and comprise:
a first structure disposed over the upper surface of pixel structures, the first structure comprising a first composition; and
a second structure disposed over the first structure, the second structure including an extension extending laterally past a sidewall of first structure;
a protective layer disposed between the pixel structures and the first structure of the overhang structures, the protective layer includes a metal-containing material having a greater etch resistivity than the first composition of the first structure;
an organic light-emitting (OLE) material disposed over the anode; and
a cathode disposed over the OLE material.

12. A method of forming a sub-pixel, comprising:
depositing a protective material, a first structure layer, and a second structure layer over a substrate, adjacent pixel structures are disposed over the substrate and expose a metal-containing layer of an anode;
disposing and patterning a resist over the second structure layer to expose a pixel opening;
conducting an etching process to remove the second structure layer of the pixel opening to form a second structure of adjacent overhang structures;
conducting a first etching process to remove the first structure layer of the pixel opening to form a first structure of the adjacent overhang structures, the protective material is resistant to a first etch chemistry of the first etching process; and
conducting a second etching process to remove the protective material of the pixel opening to form a protective layer disposed between the pixel structures and the first structure of the adjacent overhang structures, the metal-containing layer of the anode is resistant to a second etch chemistry of the second etching process.

13. The method of claim 12, wherein the first etch chemistry and the second etch chemistry are different.

14. The method of claim 12, wherein the second etch chemistry comprises acid, tetramethylammonium hydroxide (TMAH), an ammonia-peroxide mixture (APM), or hydrogen peroxide (H₂O₂).

15. The method of claim 12, wherein a first adhesion layer is in contact with the pixel structures, the protective layer is in contact with the first adhesion layer, and the first structure is in contact with the protective layer.

16. The method of claim 15, wherein a second adhesion layer is disposed between the first structure and the second structure.

17. The method of claim 12, wherein the first structure or the second structure comprise aluminum (AI), aluminum neodymium (AlNd), molybdenum (Mo), molybdenum tungsten (MoW), copper (Cu), titanium (Ti), chromium (Cr), a transparent conductive oxide (TCO) material, or combinations thereof.

18. The method of claim 17, wherein the TCO material comprises IZO, ITO, IGZO, or combinations thereof.

19. The method of claim 17, wherein the first structure and the second structure include a different composition of material.

20. The method of claim 12, wherein the protective layer comprises copper, copper alloy, Ti, Ti alloy, TiN, Mo, MoN, Mo alloy, TCO, or combinations thereof.
